(19) United States
(12) Patent Application Publication
(10) Pub. No.: US 2006/0068540 A1
(43) Pub. Date: Mar. 30, 2006

(54) Sequential chemical vapor deposition - spin-on dielectric deposition process

(76) Inventors: Kyu S. Min, San Jose, CA (US); Hui-Jung Wu, Fremont, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/951,928

(22) Filed: Sep. 27, 2004

(51) Int. Cl. H01L 21/8238

(52) U.S. Cl. 438/202

(57) ABSTRACT

A method to fill a valley on a substrate comprises depositing a first material onto the substrate using a chemical vapor deposition process to partially fill the valley and depositing a second material onto the substrate using a spin-on deposition process to completely fill the valley. The chemical vapor deposition process may comprise a high-density plasma chemical vapor deposition process or a low-pressure chemical vapor deposition process. The method may further comprise depositing a sacrificial layer, performing a first curing process on the first and second materials, polishing at least the sacrificial layer to remove at least a portion of the second material, and performing a second curing process on the first and second materials.

### BACKGROUND

As the semiconductor manufacturing industry moves towards smaller feature sizes, the size and aspect ratio for trenches and vias used in shallow trench isolation (STI), pre-metal dielectric, and other isolation structures provides more challenges. Newer devices are being built using 90-nanometer (nm) or sub-90 nm processes, and STI trenches for these devices often have aspect ratios of 4.5:1 and higher. At these smaller sizes, the use of conventional gap-filling deposition processes, as described below, leads to a greater incidence of problems such as voids or cracking in trenches and vias. Other problems also increase, such as poor insulation due to low quality dielectric material being present within trenches and vias after gap fill, and the creation of large topographical surface variations post chemical vapor deposition which may pose great problems for subsequent chemical mechanical planarization (CMP) processes.

Plasma enhanced chemical vapor deposition (PECVD) is one commonly used technique in which one or more gaseous reactors are used to form a solid insulating or conducting layer on the surface of a substrate enhanced by the use of plasma. This process is advantageous because it may be used at lower temperatures. In general, PECVD enables gap fill with aspect ratios up to 3:1 to be filled. One drawback is that multiple PECVD/sputter sequential processes need to be carried out to completely fill a gap with a high aspect ratio. Even after multiple process sequences, the processes still tend to leave voids or seams in the trenches and the quality of the PECVD fill is still inferior to another deposition technique, known as high-density plasma chemical vapor deposition (HDPCVD). This process uses a higher density plasma and is known to fill gaps with aspect ratios of around 4.5:1. In some cases, the addition of species such as Helium, Hydrogen, NF₃, and SiF₄ to the deposition chemistry may be used to improve gap fill capabilities for aspect ratios up to 6:1. Gaps with higher aspect ratios, however, may not adequately be filled using HDPCVD.

Other techniques for filling gaps are low pressure chemical vapor deposition (LPCVD) and sub-atmospheric chemical vapor deposition (SACVD), both of which are performed in a vacuum environment. These processes use the chemical reaction of gaseous compounds to provide a conformal deposition. Gap fill isolation using LPCVD or SACVD is a single step, highly conformal deposition. Gaps with aspect ratios as high as 5:1 or more may be filled with this process, however, weak seams often develop in the middle of the filled valley, resulting in device failure.

Spin-on dielectrics (SOD) using silicon derivatives as a stand-alone process may be used for gap fill isolation, and have been known to fill gaps with aspect ratios as high as 10:1. The problem with SODs, however, is that the gap fill materials derived from SOD tend to have poor electrical or mechanical properties due to heterogeneous densification, high shrinkage, and incomplete oxidation. Cracking or low quality dielectric material being present within trenches and vias after gap-filling using SOD is common. Another technique that has been used is an SOD deposition followed by one of the chemical vapor deposition (CVD) processes described above. The SOD process improves the aspect ratio of the gap and the subsequent CVD process fills the gap. This technique is not suitable for sub-90 nm applications because as device dimensions decrease, the low quality SOD materials may not provide adequate electrical insulation for the smaller devices and electrical field breakdowns and leakage tend to occur.

Accordingly, improved deposition processes are needed to provide higher quality gap fill isolation for smaller devices, such as devices built using 90 nm and sub-90 nm ultra large scale integration (ULSI) processes.

### BRIEF DESCRIPTION OF THE DRAWINGS

FIG. 1 is a semiconductor wafer with high-aspect ratio structures.

FIGS. 2A to 2C demonstrate an HDP-SOD gap fill isolation process in accordance with the invention.

FIGS. 3A to 3C demonstrate a CVD-SOD gap fill isolation process in accordance with the invention.

### DETAILED DESCRIPTION

Implementations of a method to practice a sequential chemical vapor deposition (CVD) process and spin-on dielectric (SOD) process are described herein. In the following description numerous specific details are set forth to provide a thorough understanding of the implementations. One skilled in the relevant art will recognize, however, that the techniques described herein may be practiced without one or more of the specific details, or with other methods, components, materials, etc. In other instances, well-known structures, materials, or operations are not shown or described in detail to avoid obscuring certain aspects.

The sequential CVD-SOD process of the invention may be used in semiconductor wafer manufacturing. In one implementation the CVD-SOD process may be used to fill high-aspect ratio valleys found on a surface of a semiconductor wafer or other substrate. As used herein, the term “valley” may refer to any gaps, trenches, vias, or other voids found on the surface of the semiconductor wafer. The valleys may be found between or around active areas on the semiconductor wafer, and the gap fill isolation process electrically isolates these active areas. The invention may be applicable to, but not limited to, shallow trench isolation, pre-metal dielectric, or inter-metal dielectric deposition processes. In implementations of the invention, the CVD-SOD process may fill gaps with aspect ratios of 7:1 and higher, and gap widths of 50 nm and below.

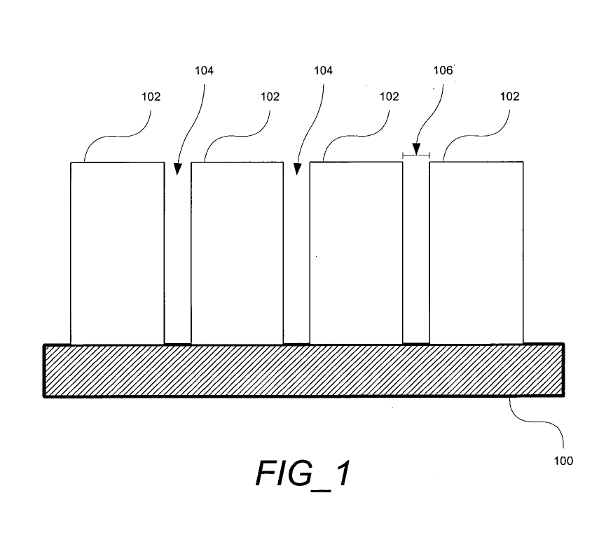

FIG. 1 illustrates a substrate 100, such as a portion of a semiconductor wafer, having several structures 102 that may be used in forming active areas. These active areas include, but are not limited to, devices such as transistors and electrical interconnections. Between the structures 102 are valleys 104. The valleys 104 include any gaps, trenches, vias, or other voids that exist between structures 102, and may also include gaps within the substrate 100 itself. Each valley 104 includes a trench opening 106. In FIG. 1, the aspect ratio of each valley 104 is approximately 7:1. Therefore, the depth of each valley 104 is approximately seven times the width of the valley 104. The width of each valley 104 is often the same as the width of trench opening 106.

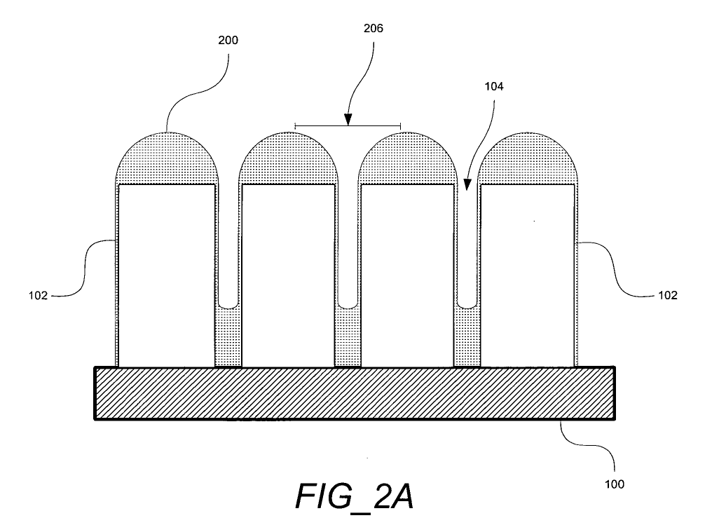

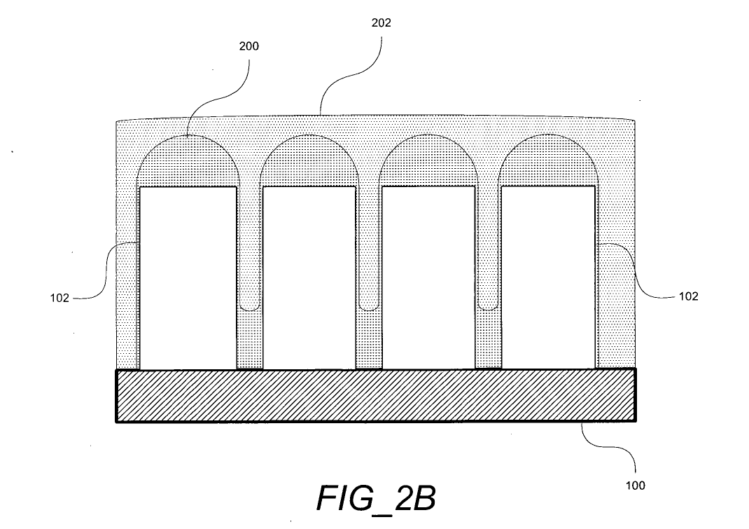

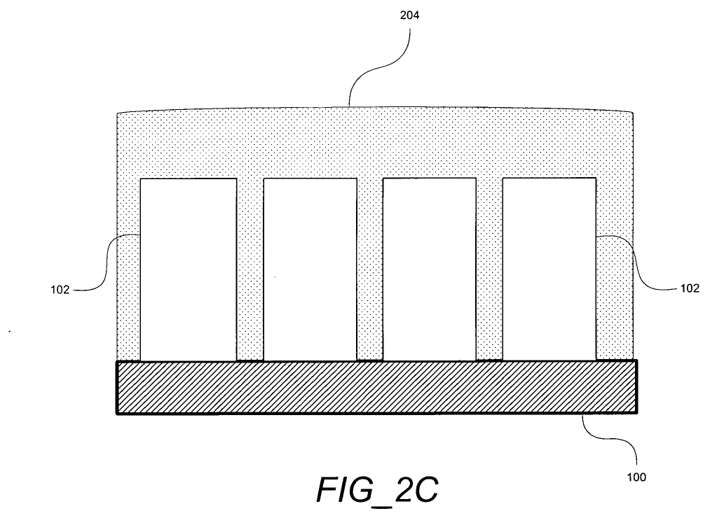

In accordance with implementations of the invention, the valleys 104 may be filled using a sequential HDPCVD-SOD process. FIG. 2A shows a first step of this process where an HDPCVD deposition process is carried out on the substrate 100 and the structures 102. The HDPCVD process deposits a high quality oxide 200 into the valleys 104 for good electrical isolation. The process provides a high bottom-to-side coverage ratio so that more of the oxide 200 may be deposited at the bottom of the valleys 104 than on the sides of the structures 102. The HDPCVD process shown in FIG. 2A reduces the aspect ratio of the valley 104 and provides each partially-filled valley 104 with a relatively larger opening towards the surface. The initial HDPCVD process also deposits a high-quality oxide 200 at the critical interfaces. For example, in shallow trench applications, the initial HDPCVD process provides robust electrical isolation at trench corners and sidewalls.

If used alone, the HDP deposition generally leads to voids and may not adequately handle valleys 104 with high aspect ratios. Therefore, in accordance with the invention, FIG. 2B illustrates a second step of the sequential process involving an SOD deposition. After the oxide 200 has been deposited by the HDPCVD process, an SOD process may be carried out to fill the valleys 104 with a dielectric material 202. The spin-on process substantially completes the filling of the valleys 104 with dielectric material 202 so that the overall fill is void-free. Within each valley 104, the SOD dielectric material 202 sits atop the oxide 200.

The spin-on process used to deposit the dielectric material 202 may be self-planarizing; accordingly, the dielectric material 202 may have a top surface that is substantially planarized. Furthermore, in some implementations the SOD process may leave a sacrificial layer of dielectric material 202 over the structures 102 for optimal chemical mechanical polishing (CMP). The sacrificial layer may be polished by the CMP process until a thin layer of the sacrificial layer remains atop the oxide 200, or until at least a portion of the oxide 200 is exposed.

The addition of the SOD deposition may provide void-free trench-fill after the initial HDP deposition because the SOD deposition has gap fill capability that is less sensitive to trench profiles such as reentrant trench sidewalls. In addition, the self-planarizing nature of the SOD deposition enables high within-die thickness uniformity for optimized pre and post CMP uniformity. In an implementation of the invention, the sequential process described herein may be capable of providing a gap fill capability exceeding a 7:1 aspect ratio with gap space of 50 nm or less, and optimal planarized topography to enable better CMP process control.

After the SOD process, in an implementation of the invention a thermal curing process may be carried out. The thermal curing process may be used for cross-linking, oxidation, and densification of the SOD. During the thermal curing process, organic compounds may be driven out of the SOD dielectric material 202 while oxygen molecules may be driven into the dielectric material 202. FIG. 2C illustrates the result of the thermal curing process in which a now relatively uniform and void-free dielectric material 204 fills the valleys 104. In other implementations of the invention, the oxide 200 and the dielectric material 202 may be cured through the application of ultraviolet (UV) radiation or other means of high energy treatment. In such an implementation, the oxide 200 and the dielectric material 202 must be UV-curable materials.

The initial HDPCVD process may result in an oxide profile that is very favorable for the subsequent SOD thermal curing process. As shown in FIG. 2A, the HDPCVD process reduces the aspect ratio of the valley 104 while providing each partially-filled valley 104 with a new, relatively larger trench opening 206 compared to the original trench opening 106 (shown in FIG. 1). During the thermal curing process, the large angle of acceptance provided by the new trench opening 206 may allow organics to more easily diffuse out of the dielectric material 202 and may allow oxygen to more easily diffuse into the dielectric material 202. The result may be a cured dielectric material 202 that provides a more crack-free, high-quality isolation.

In an implementation, an optional thermal curing process may be conducted after the sacrificial layer of dielectric material 202 over the structures 102 has been polished by the CMP process. Since either a thin layer or no layer of the sacrificial layer may remain atop the oxide 200 after the CMP process, the diffusion path will be shortened and therefore the SOD densification will be further improved. The shortened diffusion path may allow organics to more easily diffuse out of the dielectric material 202 and allow oxygen to more easily diffuse into the dielectric material 202.

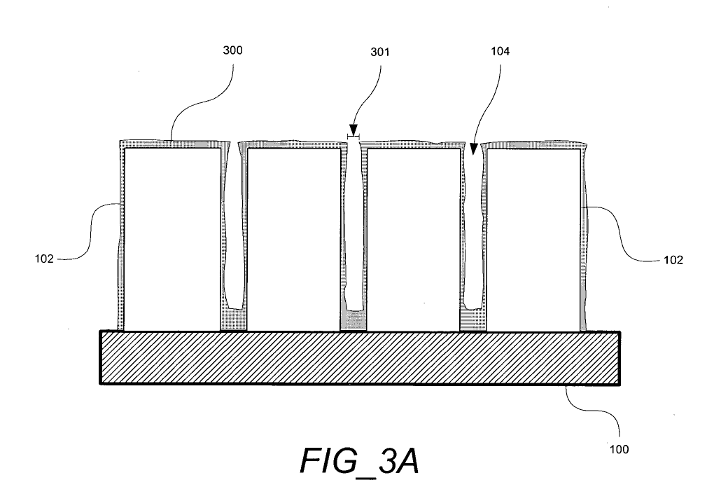

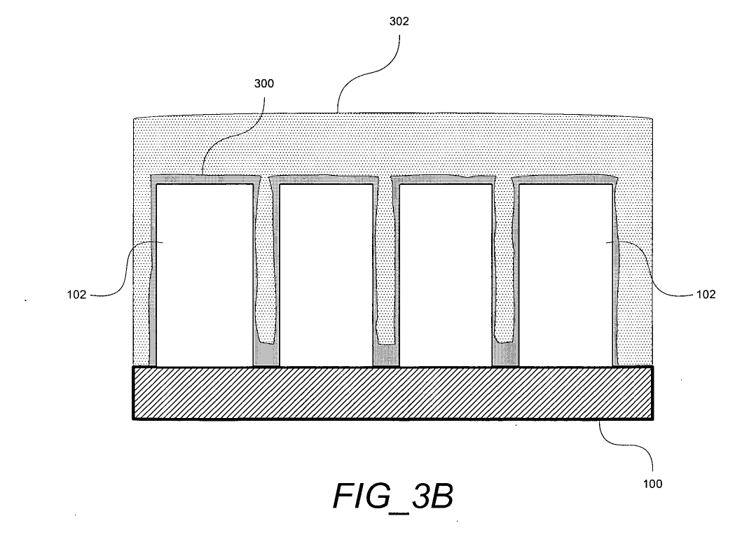

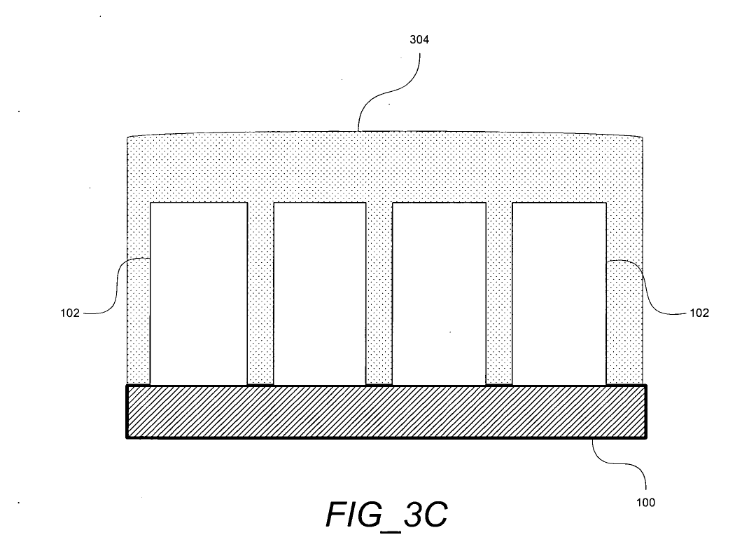

FIGS. 3A to 3C demonstrate another implementation of the invention. In the process shown, an alternative CVD process, such as LPCVD or SACVD, may be used to provide a high quality oxide and good interface at critical isolation regions. FIG. 3A shows a first step of this process where an LPCVD or SACVD deposition process is carried out on the substrate 100 and the structures 102. Similar to the HDPCVD process, the LPCVD or SACVD process deposits a high quality oxide 300 into the valleys 104 at the critical interfaces for good electrical isolation. The LPCVD/SACVD process shown in FIG. 3A reduces the aspect ratio of the valley 104, however, unlike the HDPCVD process, the aspect ratio for trench openings 301 after the LPCVD/SACVD process may not be smaller than the original trench openings 106. This is generally because the LPCVD/SACVD process is a more conformal process than the HDPCVD process. The trench profile after LPCVD/SACVD may also become reentrant which means only the SOD process may generally provide satisfactory gap fill capability.

In sub-90 nm applications, the oxide profile after the initial LPCVD or SACVD process may tend to have an open seam or a narrow void due to the conformal deposition characteristics. The seams or voids may be very small and tend to be difficult for conventional CVD processes to fill. In accordance with the invention, however, such a seam or narrow void may be filled by a subsequent SOD process. Furthermore, because the seam or void will generally have a small volume, any shrinkage that occurs due to SOD densification will have a minimal impact on the overall trench isolation performance.

FIG. 3B illustrates this subsequent step of the LPCVD/SACVD-SOD process according to the invention. After the oxide 300 has been deposited by the LPCVD/SACVD process, an SOD process may be carried out to fill the remainder of the valleys 104 with a dielectric material 302. The spin-on process substantially completes filling the valleys 104 with dielectric material 302 so that the overall fill is void-free. Within each valley 104, the dielectric material 302 may sit atop the oxide 300. And as described above, the spin-on process used to deposit the dielectric material 302 may be self-planarizing; accordingly, the dielectric material 202 may have a top surface that is substantially planarized and may act as a sacrificial layer for an optimized CMP process.

After the SOD process, in an implementation of the invention a thermal curing process may be carried out. The thermal curing process may be used for cross-linking, oxidation, and densification of the SOD. As described above, during the thermal curing process organic compounds may be driven out of the dielectric material 302 while oxygen molecules may be driven in. FIG. 3C illustrates the result of the thermal curing process in which a now relatively uniform and void-free dielectric material 304 fills the alleys 104.

In some implementations, the HDPCVD process conditions for 200 nm semiconductor wafers using an Applied Materials Ultima Plus™ system may include the following:
1) Top/Side Source Radio Frequency (RF): 2.0 Mhz
2) Bias RF: 13.56 Mhz
3) Top Coil Source RF Power: 100-5000 Watts
4) Side Coil Source RF Power: 100-5000 Watts
5) Bias RF Power: 100-5000 Watts
6) Pressure: 2-50 mTorr
7) Key gases for deposition: SiH₄ and O₂ at 20-500 std cubic cm per min (sccm)
8) Optional gases for deposition: Ar, He, SiF₄, and NF₃ at 20-500 sccm.

In some implementations, the SACVD process conditions for 200 mm semiconductor wafers using an Applied Materials Ultima Plus™ system may include the following range of tetraethylorthosilicate (TEOS) based conditions:
1) Temperature: 200-600° C.
2) Pressure: 300-760 torr
3) O₂ flow rate: 3000-12,000 sccm
4) O₃ concentration in O₂: 3-10%
5) Dilution N₂ at 9,000-27,000 sccm
6) TEOS/N₂ at 500-1500 sccm
7) O₃/TEOS ratio of 5:1 to 25:1.

In some implementations, the SOD process conditions may include a dielectric material composed of silicon containing polymers dissolved or dispensed in suitable solvents. The dielectric material may be applied to the substrate by spin coating under the following process conditions:
1) Substrate rotation speed of 500 to 4000 RPM
2) Baking at 100° C. to 400° C. in an inert or an oxidative atmosphere
3) Optional cure at 400° C.-500° C. for 2 min to 3 hr
4) Additional high temp cure at 600° C.-900° C. in inert or oxidative atmosphere to fully converted the cured film to oxide.

In some implementations, the SOD film may exhibit oxide-like properties after the high temperature cure. Other high energy processes may be used to achieve the same effect. The high temperature cure may also be performed after the CMP to shorten the diffusion path.

In some implementations, the SOD process conditions may include the following:
1) Apply SOD while substrate is static
2) Spin substrate at 500 RPM for 3 sec
3) Spin substrate at 1000 RPM for 2 sec
4) Spin substrate at 3000 RPM for 30 sec
5) Bake at 150° C. for 1 min in N₂ or air
6) Bake at 250° C. for 1 min in N₂ or air
7) Bake at 350° C. for 1 min in N₂ or air
8) Cure at 450° C. for 1 hr in air
9) High temp steam cure at 850° C. for 1 hr in O₂ with water vapor.

In implementations of the invention, the methods described above may be carried out on separate tools for the chemical vapor deposition process and the subsequent spin-on dielectric process. For instance, the CVD process may be carried out in a CVD chamber, and the SOD process may then be carried out on a SOD tool. In some implementations, a combined system may be used that includes a spin-on dielectric tool within a chemical vapor deposition chamber. Known CVD systems and known SOD tools may be used to carry out the methods described above.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize. For example, implementations of the invention include CVD processes other than HDPCVD, LPCVD, and SACVD.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method to fill a valley on a substrate comprising:
depositing a first material onto the substrate using a chemical vapor deposition process to partially fill the valley; and
depositing a second material onto the substrate using a spin-on deposition process to completely fill the valley.

2. The method of claim 1, further comprising curing the first and second materials.

3. The method of claim 1, wherein the substrate comprises a semiconductor wafer.

4. The method of claim 3, wherein the valley comprises a gap, a trench, or a via on a surface of the semiconductor wafer.

5. The method of claim 1, wherein the first material comprises an oxide.

6. The method of claim 1, wherein the second material comprises a spin-on dielectric material.

7. The method of claim 1, wherein the chemical vapor deposition process comprises a high-density plasma chemical vapor deposition process.

8. The method of claim 1, wherein the chemical vapor deposition process comprises a low-pressure chemical vapor deposition process.

9. The method of claim 1, wherein the chemical vapor deposition process comprises a sub-atmospheric chemical vapor deposition process.

10. The method of claim 2, wherein the curing of the first and second materials comprises a thermal curing of at least one of the first or second materials.

11. The method of claim 2, wherein the curing of the first and second materials comprises a high energy curing of at least one of the first or second materials.

12. The method of claim 11, wherein the high energy curing comprises an ultraviolet radiation curing.

13. The method of claim 1, wherein the depositing of the second material onto the substrate further comprises depositing a sacrificial layer.

14. The method of claim 13, further comprising:
performing a first curing process on the first and second materials;
polishing at least the sacrificial layer to remove at least a portion of the second material; and
performing a second curing process on the first and second materials.

15. The method of claim 14, wherein the first and second curing processes are thermal curing processes.

16. The method of claim 14, wherein the first and second curing processes are high energy curing processes.

17. The method of claim 16, wherein the high energy processes are ultraviolet radiation curing processes.

18. A method to fill a valley on a substrate comprising:
depositing a first material into the valley using a high-density plasma chemical vapor deposition process to partially fill the valley;
depositing a second material into the valley using a spin-on dielectric process to completely fill the valley and to form a sacrificial layer; and
curing at least the second material.

19. The method of claim 18, wherein the first material is a dielectric material.

20. The method of claim 18, wherein the second material is a dielectric material.

21. The method of claim 18, further comprising planarizing the second material using a chemical mechanical polishing process.

22. The method of claim 21, further comprising performing a second cure on at least the second material subsequent to the chemical mechanical polishing process.

23. The method of claim 18, wherein the curing of the second material comprises a thermal curing, a high energy curing, or an ultraviolet radiation curing.

24. The method of claim 22, wherein the second cure comprises a thermal curing process, a high energy curing process, or an ultraviolet curing process.

25. An apparatus to fill a valley on a substrate, comprising:
a chemical vapor deposition chamber; and
a spin-on dielectric tool within the chemical vapor deposition chamber.

26. The apparatus of claim 25, wherein the chemical vapor deposition chamber comprises a high-density plasma chemical vapor deposition chamber.

27. The apparatus of claim 25, wherein the chemical vapor deposition chamber comprises a low-pressure chemical vapor deposition chamber.

28. A substrate comprising:
a valley, wherein the valley comprises:
a first layer deposited within the valley, wherein the first layer is deposited by a chemical vapor deposition process, and
a second layer deposited atop the first layer, wherein the second layer is deposited by a spin-on deposition process.

29. The substrate of claim 28, wherein the chemical vapor deposition method comprises a high-density plasma chemical vapor deposition process.

30. The substrate of claim 28, wherein the valley comprises a gap, a trench, or a via on a surface of the substrate.
